(19) United States
(12) Patent Application Publication
(10) Pub. No.: US 2006/0208633 A1
(43) Pub. Date: Sep. 21, 2006

(54) Organic electroluminescent device with improved lifetime and method for fabricating the same

(76) Inventors: Chi-Ming Cheng, Chu-Nan (TW); Chih-Hung Yeh, Chu-Nan (TW); Hui-Chang Yu, Chu-Nan (TW); Wei-Wen Yang, Chu-Nan (TW); Chin Chung Chang Chien, Chu-Nan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/270,575

(22) Filed: Nov. 10, 2005

(30) Foreign Application Priority Data
Mar. 18, 2005 (TW) 094108467

(51) Int. Cl. H01J 1/62; H01J 63/04

(52) U.S. Cl. 313/504

(57) ABSTRACT

An organic electroluminescent device with improved lifetime and a method of fabricating the same are provided. The device comprises a barrier layer on an upper surface of a color filter, and etching and removing part of the barrier layer uncovered by first electrodes to form moistness removed channel after defining and forming at least one first electrode on an upper surface of the barrier layer. It is convenient to bake and eliminate a solvent or mist existed in the color filter in a baking process, thereby reducing speed of going bad of the organic light emitting layer and effectively improving lifetime of the organic electroluminescent device.

### FIELD OF THE INVENTION

The present invention is related to an organic electroluminescent device and more particularly to an organic electroluminescent device with improved lifetime and a method of fabricating the same.

### BACKGROUND

By the vigorous development of optic-electronic industry, people enjoy the convenience brought by science and technologies. However, how to make plane display or light emitting device with high quality and low cost is always an object to be achieved by various factories. In various displays and light emitting devices, organic electroluminescent device (OLED) has advantages of self-radiating, high brightness, wide visual angle, low power consuming, high responding speed, light and thin panel, simple element structure and process in comparison with other light emitting devices, and it thus is paid more attention by research units and factories in various countries.

For various displays or light emitting devices, how to achieve full color display is always a key to succeed. For organic electroluminescent display, there are three common ways to achieve full color display:
1. trichromatic light emitting layer structure: it is a light emitting device by mainly using organic electroluminescent elements of three primary colors, red (R), green (G), and blue (B), to emit light alone to directly get full color effect.
2. color change media (CCM): mainly uses a blue light emitting organic electroluminescent device and collocates with a color change media to get light of three primary colors (RGB) thereby to achieve full color display.
3. color filter (CF): mainly uses a white light emitting organic electroluminescent device and collocates with a color filter to generate full color display effect after filtering the white light by color filter.

Among them, general color change media or color filter structures are shown in FIG. 1. The main structure of the color filter 11 is defining and setting a plurality of black matrixes 117 on a transparent substrate 119, and providing a color filtering layer 115 on an upper surface of the transparent substrate 119 which is not set the black matrixes 117 to filter light. Further, an over coat 113 and a barrier layer 111, such as silica layer. The over coat 113 and barrier layer 111 are deposited in sequence on the black matrixes 117 and color filtering layer 115 to protect the color filtering layer 115 and black matrixes 117 and be beneficial to set an organic electroluminescent element 13. The organic electroluminescent element 13 uses a transparent conductive material as a material of a first electrode 131, such as ITO, and grows an organic light emitting layer 133 and a second electrode 135 in sequence on the first electrode 131.

However, in the fabricating process of the color filter 11, partial mist or some working solvent is hard to remove, if there are some residual mist or solvent in the over coat 113. The residual mist will easily pass through the over coat 113 and barrier layer 111 and interacts with the organic light emitting layer 133 of the organic electroluminescent element 13 to further cause the organic light emitting layer 133 going bad and affect lifetime of the organic electroluminescent device 10. To this end, a drainage process has to be proceeded by baking the color filter before the organic electroluminescent element 13 grown on the color filter 11 to remove residual mist or solvent in the color filter 11. A general prior art processing way is sending the color filter 11 into a high temperature oven to bake to remove residual mist or solvent in the color filter 11 and prevent the residual mist or solvent in the color filter 11 from interacting with the organic electroluminescent element 13 after completing packaging the organic electroluminescent device 10.

Although the residual mist or solvent in the color filter 11 can be removed by the previous mentioned method; however, since the barrier layer 111 is unfavorable to pass the mist or solvent in the baking process such that effect and efficiency of the drainage process of the color filter 11 cannot be manifest, and the lifetime of the organic electroluminescent device 10 cannot be effectively improved, either.

### SUMMARY OF THE INVENTION

Accordingly, how to design a novel organic electroluminescent device with improved lifetime and a method of fabricating the same to achieve an object of effectively removing residual mist or solvent in the color filter and to further extend lifetime of the organic electroluminescent device with respect to the previous mentioned problems encountered by the prior art is the key point of the present invention.

It is a primary object of the present invention to provide an organic electroluminescent device with improved lifetime which digs a moistness removed channel on part of barrier layer uncovered by first electrodes to be beneficial to removing mist or solvent existed in the color filter in a baking process to effectively improve lifetime of the organic electroluminescent device.

It is a secondary object of the present invention to provide a method of fabricating an organic electroluminescent device with improved lifetime which uses a simple and easy step of etching the barrier layer to form a moistness removed channel beneficial to eliminating mist or solvent in the color filter thereby reducing speed of going bad of an organic light emitting layer and effectively improve lifetime of the organic electroluminescent device.

To achieve the previous mentioned objects, an organic electroluminescent device with improved lifetime, comprising: a color filter comprising a transparent substrate, a color resist and an over coat deposited in sequence on an upper surface of the transparent substrate, and at least one barrier layer and at least one moistness removed channel provided respectively on an upper surface of the over coat, and the moistness removed channel provided next to the barrier layer; and an organic electroluminescent element comprising a first electrode fixed on an upper surface of said barrier layer, and an organic light emitting layer and a second electrode deposited in sequence on a partial upper surface of the first electrode.

The present invention further provides a method of fabricating an organic electroluminescent device with improved lifetime, comprising the steps of: defining and forming at least one first electrode on a partial upper surface of a barrier layer of a color filter, and naturally defining the other part of the barrier layer uncovered by the first electrode as an exposed barrier layer; removing the exposed barrier layer to form a moistness removed channel; proceeding a drainage process to the color filter to eliminate mist existed in the color filter by said moistness removed channel; and forming an organic light emitting layer and a second electrode in order on an upper surface of the first electrode.

### BRIEF DESCRIPTION OF DRAWINGS

FIG. 1 is a structural diagram of a prior art organic electroluminescent device.

FIG. 2 is a sectional diagram of a preferred embodiment of an organic electroluminescent device of the present invention.

FIG. 3A to FIG. 3C are respectively structural sectional diagrams of each process step of an embodiment of the present invention.

FIG. 4 is a fabricating flow chart of an embodiment of the present invention.

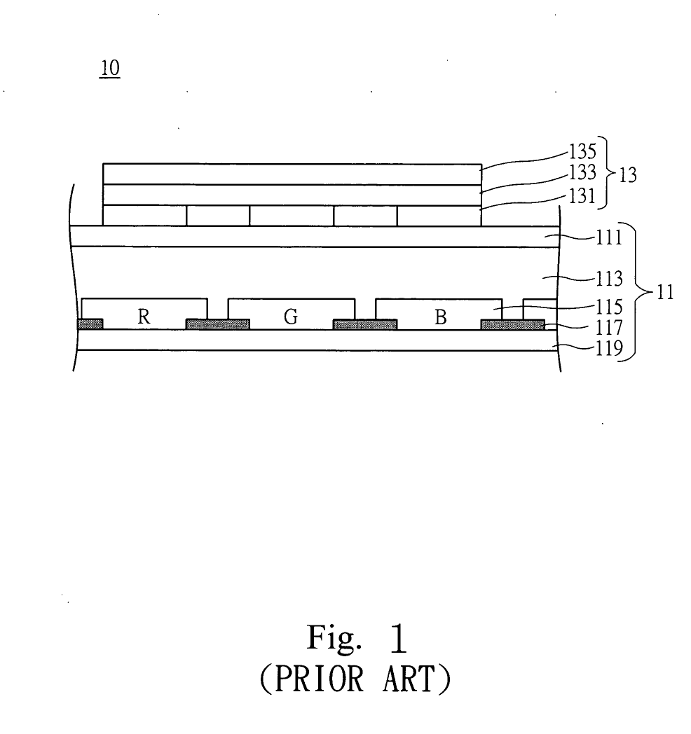

### DETAILED DESCRIPTION

The structural features and the effects to be achieved may further be understood and appreciated by reference to the presently preferred embodiments together with the detailed description.

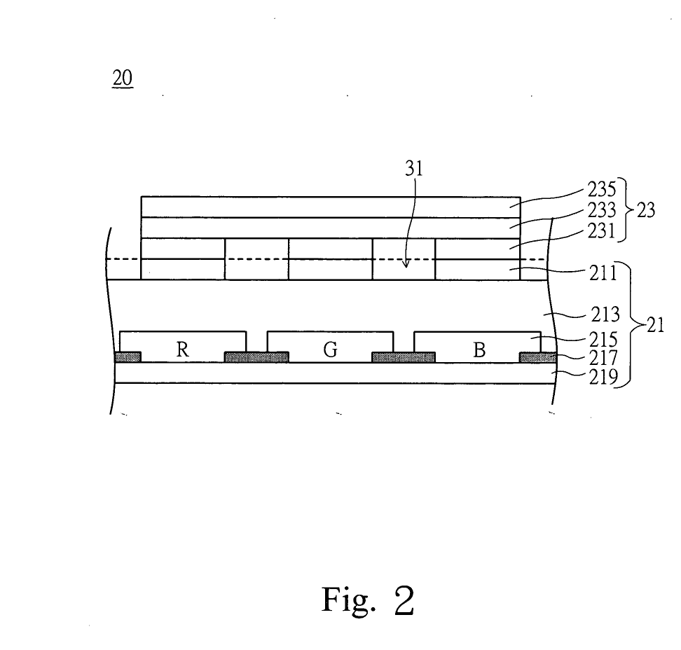

Firstly, please refer to FIG. 2, a sectional diagram of a preferred embodiment of an organic electroluminescent device of the present invention. As shown, the organic electroluminescent device 20 with improved lifetime of the present invention mainly provides at least one organic electroluminesent element 23 on a color filter 21. Among them, a structure of the color filter 21 is providing at least one black matrix 217 on an upper surface of a transparent substrate 219 and providing at least one color resist 215 on the upper surface of the transparent substrate 219, which does not provide the black matrix 217. Further, an over coat 213 and a barrier layer 211, such as silica layer, silicon nitride layer, or silicon oxynitride, are provided in order on the black matrix 217 and color resist 215. An object of leveling the color filter 21 and reducing mist or working solvent existed in the color filter 21 can be achieved by providing the over coat 213 and barrier layer 211.

The first electrode 231 is made by a transparent conductive material, such as ITO (indium tin oxide), and uses a metal with lower work function as a material of the second electrode 235, such as magnesium, calcium, aluminum, lithium, etc. Further, an organic light emitting layer 233 is grown between the second electrode 235 and first electrode 231. After both of the electrodes 231/235 are electrified, an object of emitting light from the organic electroluminescent element 23 is achieved. Among them, the first electrode 231 is fixed on a partial upper surface of the barrier layer 211, and a moistness removed channel 31 is dug and provided in partial barrier layer 211 uncovered by the first electrode 231 to be beneficial to proceeding drainage process of the color filter 21.

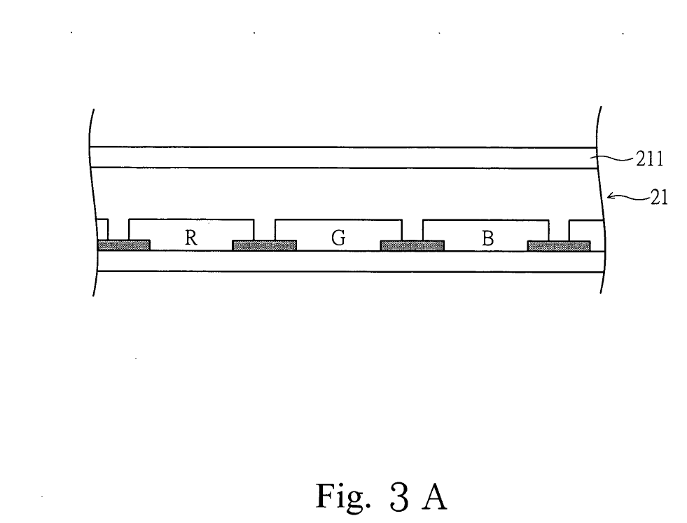

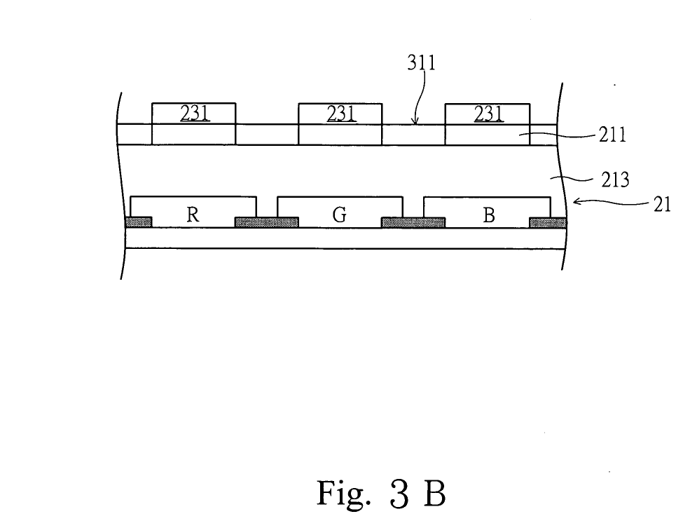

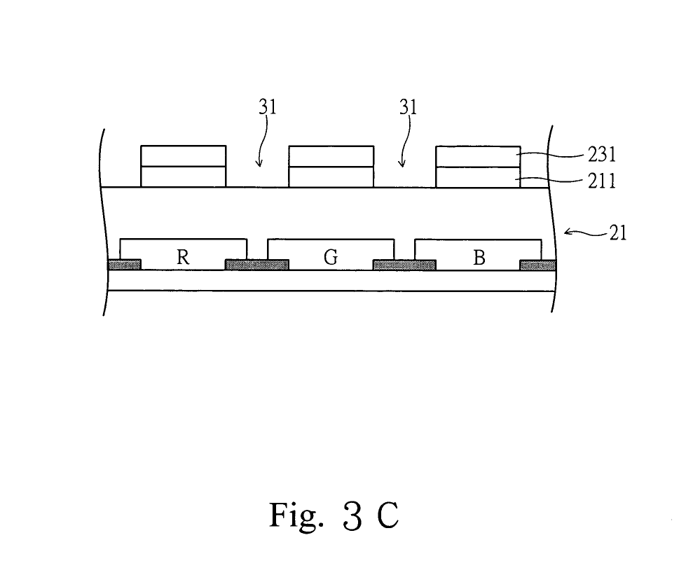

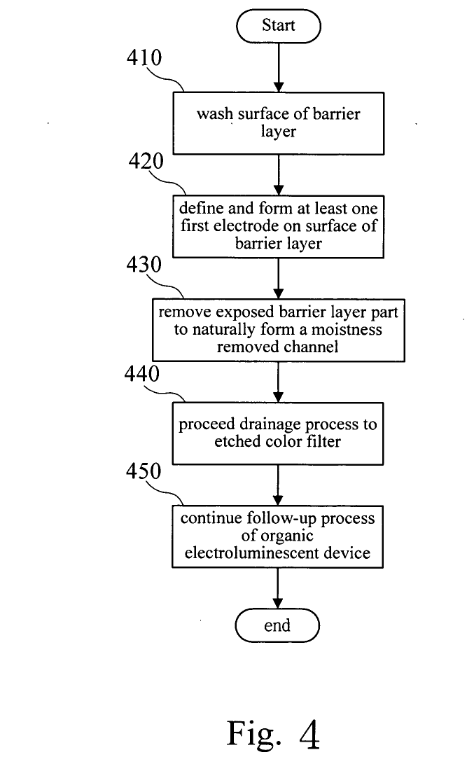

Furthermore, please simultaneously refer to FIG. 3A, FIG. 3B, FIG. 3C, and FIG. 4, respectively are structural sectional diagrams and fabricating flow chart of each process step of the previous mentioned embodiment of the present invention. As shown, the main fabricating flow of the organic electroluminescent device 20 is as follows: First, wash the barrier layer 211 of the color filter 21, and the cleaning method is the same as a flow of washing a silicon chip in a general process, as shown in step 410 and FIG. 3A. After finishing washing the barrier layer 211, form a conduction layer on the clean surface of the barrier layer 211. To define and form at least one first electrode 231 by the process of lithography and etching on the surface of the barrier layer 211, while part of the barrier layer 211 uncovered by the first electrode 231 will be exposed and naturally defined as an exposed barrier layer 311, as shown in step 420 and FIG. 3B.

After finishing the step of forming the first electrode 231, continue proceeding a removing or etching procedure of the exposed barrier layer 311 uncovered by the first electrode 231. For example, choose different etching/removing ways depending on difference of the material of the barrier layer 211. If the barrier layer 211 is made from silica, wet or dry etching method can be chosen to proceed etching silica. If wet etching way is chosen to proceed etching, the etching liquid used can be B.O.E. (NH₄F (40% ): HF (49%)=6:1), HF (hydrofluoric acid), BHF or KOH (potassium hydroxide) to achieve an object of etching silica and removing the exposed barrier layer 311. Additionally, if the barrier layer 211 is made from silicon nitride or silicon oxynitride, then the etching step can be chosen as a dry etching way, the exposed barrier layer 311 can also be removed to naturally form a moistness removed channel 31, as shown in step 430 and FIG. 3C.

Owning to removing the exposed barrier layer 311 uncovered by the first electrode 231 and forming a moistness removed channel 31 in the previous mentioned step, it is beneficial to proceeding the drainage process of the color filter 21 and achieving an object of residual mist or working solvent remaining in the color filter 21 by providing the moistness removed channel 31. The method of the drainage process can be chosen as using a high temperature oven to proceed a baking procedure of the color filter 21 or an illumination way to achieve an object of removing mist or solvent inside of the color filter 21. Besides, when the baking or illumination way is used to proceed the drainage process of the color filter 21, it can be proceeded in a vacuum environment. This way, not only mist or solvent contained inside of the color filter 21 can be truly removed, but also the efficiency of the drainage process can be effectively improved to save time and cost spent in the drainage process, as shown in step 440.

After finishing the step of vacuum baking of the color filter 21, follow-up process of the organic electroluminescent device 20 can be continued proceeding. For example, grow an organic light emitting layer 233 and a second electrode 235 are grown in order on a surface of the first electrode 231 to complete the fabrication of the organic electroluminescent element 23, as shown in step 450 and FIG. 2.

Thanks to fully removing mist or solvent inside of the color filter 21 before proceeding follow-up process of the organic electroluminescent device 20, the possibility of interacting the organic electroluminescent element 23 or organic light emitting layer 233 with the mist can be effectively reduced to achieve an object of reducing the speed of going bad of the organic light emitting layer 233 and improving the lifetime of the organic electroluminescent device 20

In the previous mentioned embodiment of the present invention, the color filter 21 is specifically described as an inventive embodiment. However, in alternate embodiments, the color filter 21 can be also chosen as a color change media (CCM). The object of removing mist or solvent inside of the color change media and improving the lifetime of the organic electroluminescent device 20 can also be achieved.

In summary, it is appreciated that the present invention is related to an organic electroluminescent device and more particularly to an organic electroluminescent device with improved lifetime and a method of fabricating the same. Therefore, the present invention should be granted a patent.

The foregoing description is merely one embodiment of present invention and not considered as restrictive. All equivalent variations and modifications in process, method, feature, and spirit in accordance with the appended claims may be made without in any way from the scope of the invention.

1. An organic electroluminescent device with improved lifetime, comprising:
a color filter comprising a transparent substrate, a color resist and an over coat deposited in sequence on an upper surface of said transparent substrate, and at least one barrier layer and at least one moistness removed channel provided respectively on an upper surface of said over coat, and said moistness removed channel provided next to said barrier layer; and
an organic electroluminescent element comprising a first electrode fixed on an upper surface of said barrier layer, and an organic light emitting layer and a second electrode deposited in sequence on a partial upper surface of the first electrode.

2. The organic electroluminescent device according to claim 1, wherein said barrier layer is selected from one of a silica layer, a silicon nitride layer, and a silicon oxynitride.

3. The organic electroluminescent device according to claim 1, wherein said color filter is a color changing media.

4. A method of fabricating an organic electroluminescent device with improved lifetime, comprising the steps of:
defining and forming at least one first electrode on a partial upper surface of a barrier layer of a color filter, and naturally defining the other part of said barrier layer uncovered by the first electrode as an exposed barrier layer;
removing said exposed barrier layer to form a moistness removed channel;
proceeding a drainage process to said color filter to eliminate mist existed in said color filter by said moistness removed channel; and
forming an organic light emitting layer and a second electrode in order on an upper surface of the first electrode.

5. The fabricating method according to claim 4, wherein said drainage process is selected from one of a baking mode and an illumination mode.

6. The fabricating method according to claim 5, wherein said drainage process is proceeded under a vacuum environment.

7. The fabricating method according to claim 4, wherein said barrier layer is selected from one of a silica layer, a silicon nitride layer, and a silicon oxynitride.

8. The fabricating method according to claim 4, wherein said color filter is a color changing media.
